(19) United States
(12) Patent Application Publication
(10) Pub. No.: US 2016/0211357 A1
(43) Pub. Date: Jul. 21, 2016

(54) SEMICONDUCTOR DEVICE

(71) Applicant: KABUSHIKI KAISHA TOSHIBA, Tokyo (JP)

(72) Inventors: Hung HUNG, Nonoichi Ishikawa (JP); Yasuhiro ISOBE, Kanazawa Ishikawa (JP); Kohei OASA, Nonoichi Ishikawa (JP); Akira YOSHIOKA, Nomi Ishikawa (JP)

(21) Appl. No.: 14/831,460

(22) Filed: Aug. 20, 2015

(30) Foreign Application Priority Data
Jan. 21, 2015 (JP) 2015-009588

(51) Int. Cl. H01L 29/778; H01L 29/205; H01L 29/207; H01L 29/66; H01L 29/861; H01L 27/06; H01L 29/20; H01L 29/36

(52) U.S. Cl. CPC H01L 29/7787; H01L 29/2003; H01L 29/205; H01L 29/36; H01L 29/66462; H01L 29/66136; H01L 29/861; H01L 27/0629; H01L 27/0605; H01L 29/207

(57) ABSTRACT

A semiconductor device includes a first semiconductor layer on a substrate, a second semiconductor layer comprising a nitride semiconductor doped with p-type dopants on the first semiconductor layer, a third semiconductor layer comprising an undoped nitride semiconductor on the second semiconductor layer, a fourth semiconductor layer comprising an undoped nitride semiconductor on the third semiconductor layer, and a fifth semiconductor layer on the fourth semiconductor layer, the fifth semiconductor layer comprising a nitride semiconductor having a band gap greater than a band gap of the fourth semiconductor layer.

### CROSS-REFERENCE TO RELATED APPLICATION

This application is based upon and claims the benefit of priority from Japanese Patent Application No. 2015-009588, filed Jan. 21, 2015, the entire contents of which are incorporated herein by reference.

### FIELD

Embodiments described herein relate generally to a semiconductor device, and relate to a semiconductor device using a compound semiconductor.

### BACKGROUND

In a circuit of switching power-supply, an inverter, or the like, a power semiconductor element or device incorporating a switching element or a diode is used, and high breakdown voltage and low on-resistance are required for the power semiconductor device. There is a trade-off relationship between the breakdown voltage and the on-resistance of the power semiconductor device, which is determined according to the semiconductor device material used. When a wide band gap semiconductor such as a nitride semiconductor or silicon carbide (SiC) is used as the element material, it is possible to improve the trade-off relationship between on-resistance and breakdown voltage as compared to the case where silicon is used as the device element material, and it is possible to provide a power semiconductor device having high breakdown voltage and low on-resistance.

A power semiconductor device formed using a nitride semiconductor such as GaN or AlGaN has excellent material properties, and thus one is able to provide a power semiconductor element having high performance. In particular, in a High Electron Mobility Transistor (HEMT) having a heterojunction structure of an AlGaN layer and a GaN layer, a high concentration two-dimensional electron gas is generated due to polarization in a boundary surface between the AlGaN layer and the GaN layer, and thus it is possible to achieve low on-resistance in the power semiconductor device.

### DESCRIPTION OF THE DRAWINGS

FIG. 1 is a cross-sectional view of a semiconductor device according to an embodiment.

FIG. 2 is a schematic view illustrating an operation of the semiconductor device.

FIG. 3 is an energy band diagram of the semiconductor device.

FIG. 4 is a graph illustrating a relationship between a drain voltage and a leak current.

### DETAILED DESCRIPTION

An exemplary embodiment provides a semiconductor device having a further reduced leakage current.

In general, according to one embodiment, a semiconductor device includes a first semiconductor layer on a substrate; a second semiconductor layer comprising a nitride semiconductor doped with p-type dopants on the first semiconductor layer; a third semiconductor layer comprising an undoped nitride semiconductor on the second semiconductor layer; a fourth semiconductor layer comprising an undoped nitride semiconductor on the third semiconductor layer; and a fifth semiconductor layer on the fourth semiconductor layer, the fifth semiconductor layer comprising a nitride semiconductor having a band gap greater than a band gap of the fourth semiconductor layer.

Hereinafter, an embodiment will be described with reference to the drawings. However, the drawings are schematically or conceptually illustrated, and the dimension and the scale of the respective drawings are not necessarily identical to the actual dimension and scale of an actual semiconductor element. Some embodiments described hereinafter are exemplifications of a device and a method for specifying the technological concept of an exemplary embodiment, and the technological concept of the exemplary embodiment is not limited to the shape, the structure, the disposition or the like of structures. Furthermore, in the following description, the same reference numerals are applied to structures having the same function and the same configuration, and the description thereof will be repeated only when it is necessary.

1. Configuration of a Semiconductor Device

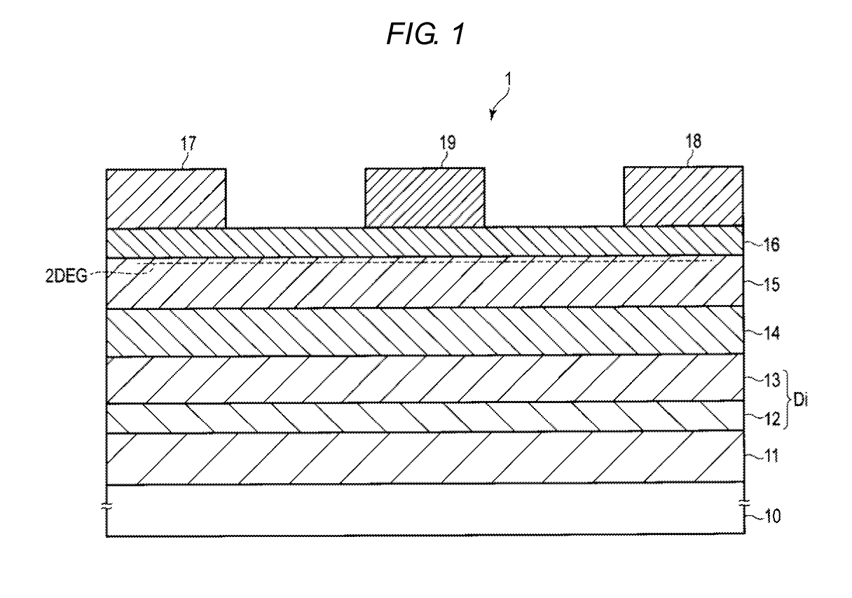

FIG. 1 is a cross-sectional view of a semiconductor device 1 according to an embodiment. The semiconductor device is a nitride semiconductor device using a nitride semiconductor as a compound of the device 1. In addition, the semiconductor device 1 is an electric field effect transistor (FET), and specifically, is a High Electron Mobility Transistor (HEMT).

A substrate 10, for example, is configured of a silicon (Si) substrate having a (111) plane as the main (upper device forming) surface thereof. As the substrate 10, silicon carbide (SiC), gallium nitride (GaN), gallium phosphide (GaP), indium phosphide (InP), gallium arsenide (GaAs), sapphire (Al₂O₃), or the like may be used. In addition, as the substrate 10, a substrate including an insulating layer is able to be used. For example, as the substrate 10, a Silicon On Insulator (SOI) substrate may be used.

A buffer layer (a first buffer layer) 11 is provided on the substrate 10. The buffer layer 11 has a function of reducing distortion which occurs due to a difference between the lattice constant of the nitride semiconductor layer formed on the buffer layer 11 and the lattice constant of the substrate 10, and of controlling crystallinity of the nitride semiconductor layer formed on the buffer layer 11. The buffer layer 11, for example, is configured of Al_{X}Ga_{1-X}N (0≦X≦1).

The buffer layer 11 may be configured by stacking a plurality of Al_{X}Ga_{1-X}N sub-layers having different composition ratios one over the other. When the buffer layer 11 is configured as a multi-sub layer stacked structure, the composition ratio of the stacked structure is adjusted such that the lattice constants of the plurality of sub layers included in the stacked structure are incrementally changed (increased) from the lattice constant of a lower layer among the upper and lower layers of the buffer layer 11 to the lattice constant of an upper layer of the buffer layer 11.

A p-type semiconductor layer 12 is provided on the buffer layer 11. The p-type semiconductor layer 12 functions as one semiconductor layer configuring a diode (a PN junction diode) Di having a rectifying action. The p-type semiconductor layer 12 is formed of Al_{X}In_{Y}Ga_{1-(X+Y)}N (0≦X<1, 0≦Y<1, and 0≦X+Y<1) doped with p-type dopants. In this embodiment, the p-type semiconductor layer 12, for example, is formed of GaN doped with p-type dopants. As the p-type dopant, magnesium (Mg) or the like is used.

The p-type semiconductor layer 12 is formed by doping the nitride semiconductor with the p-type dopant, and thus the uniformity of the crystalline structure thereof is degraded or distorted, compared to the uniformity of the crystal structure of undoped GaN. The “undoped” indicates that dopants are not intentionally incorporated into the film layer, and for example, a film layer in which small amounts of impurities or dopants are unintentionally incorporated in the layer during a manufacturing process or the like is considered “undoped”. Accordingly, from a viewpoint of suppressing an influence of the distorted crystal structure of the p-type semiconductor layer 12 on an overlying layer, it is preferable that the thickness of the p-type semiconductor layer 12 is small. The thickness of the p-type semiconductor layer 12, for example, is approximately 50 nm. By decreasing the thickness of the p-type semiconductor layer 12, it is possible to prevent crystallinity of the upper portion of the p-type semiconductor layer 12 from being degraded due to the crystallinity of the p-type semiconductor layer 12. The p-type semiconductor layer 12 is set to be thinner than the buffer layer 13 (described later).

The lattice constant of the p-type semiconductor layer 12 is greater than the lattice constant of the buffer layer 11. Accordingly, it is possible to reduce warping of the buffer layer 11 in which the buffer layer 11 and underlying substrate extend downwardly in a convex shape, and thus it is possible to reduce warpage of the resulting semiconductor device 1.

A buffer layer (a second buffer layer) 13 is provided on the p-type semiconductor layer 12. The buffer layer 13 is formed of undoped Al_{X}In_{Y}Ga_{1-(X+Y)}N (0≦X<1, 0≦Y<1, and 0≦X+Y<1). The undoped AlInGaN layer has n-type conductivity. In this embodiment, the buffer layer 13, for example, is formed of undoped GaN. The undoped GaN also has n-type conductivity.

The buffer layer 13 functions as the other semiconductor layer configuring the diode Di, and also has a function of controlling crystallinity of the nitride semiconductor layer formed on the buffer layer 13. Specifically, the buffer layer 13 prevents crystal defects in the p-type semiconductor layer 12 from being shifted or copied into the nitride semiconductor layer formed on the buffer layer 13. The thickness of the buffer layer 13, for example, is approximately 2 μm.

Furthermore, the buffer layer 13 may have n-type conductivity as a result of doping the buffer layer 13 with n-type dopants. As the n-type dopants, silicon (Si), zinc (Zn), or the like is used. In this case, the concentration of the n-type dopants in the buffer layer 13 is set to be lower than the concentration of the p-type dopants in the p-type semiconductor layer 12.

A high resistance layer (an interlayer) 14 is disposed on the buffer layer 13. The high resistance layer 14 has a function of improving the breakdown voltage of the semiconductor device 1. The resistance of the high resistance layer 14 is set to be higher than the resistance of the buffer layer 13. The high resistance layer 14 is formed of Al_{X}In_{Y}Ga_{1-(X+Y)}N (0≦X<1, 0≦Y<1, and 0≦X+Y<1) doped with carbon (C). In this embodiment, the high resistance layer 14, for example, is formed of GaN (C-GaN) doped with carbon (C). The thickness of the high resistance layer 14, for example, is approximately 2 μm. The resistance of the high resistance layer 14 is suitably set according to a desired breakdown voltage for the semiconductor device 1. The high resistance layer 14 is not essential in this embodiment, and the high resistance layer 14 may not need to be used when it is allowable for the breakdown voltage to be reduced.

A channel layer 15 is provided on the high resistance layer 14. The channel layer 15 is a layer on which a channel (a current path) of a transistor is formed. The channel layer 15 is formed of Al_{X}In_{Y}Ga_{1-(X+Y)}N (0≦X<1, 0≦Y<1, and 0≦X+Y<1). The channel layer 15 is an undoped layer, and includes a nitride semiconductor having a high degree of crystal uniformity (high quality). It is preferable that the channel layer 15 is formed by controlling a manufacturing process such that the amount of impurities or unintentionally incorporated dopants therein is further reduced. In this embodiment, the channel layer 15, for example, is formed of undoped GaN (referred to as intrinsic GaN). The thickness of the channel layer 15, for example, is approximately 1 μm.

A barrier layer 16 is disposed on the channel layer 15. The barrier layer 16 is formed of Al_{X}In_{Y}Ga_{1-(X+Y)}N (0≦X<1, 0≦Y<1, and 0≦X+Y<1). The barrier layer 16 includes a nitride semiconductor having a band gap greater than a band gap of the channel layer 15. In this embodiment, the barrier layer 16, for example, is formed of undoped AlGaN. A composition ratio of Al in an AlGaN layer as the barrier layer 16, for example, is approximately 0.2. The thickness of the barrier layer 16, for example, is approximately 30 nm.

Furthermore, the plurality of semiconductor layers configuring the semiconductor device 1 are, for example, sequentially formed by epitaxial growth using a Metal Organic Chemical Vapor Deposition (MOCVD) method. That is, the plurality of semiconductor layers configuring the semiconductor device 1 includes an epitaxial layer.

A source electrode 17 and a drain electrode 18 are provided on the barrier layer 16 and spaced from one another. Further, a gate electrode 19 is provided on the barrier layer 16 in a location between, and spaced from, both the source electrode 17 and the drain electrode 18.

The gate electrode 19 and the barrier layer 16 form a schottky junction. That is, the gate electrode 19 is configured to include a material which forms a schottky junction with the barrier layer 16. The semiconductor device 1 illustrated in FIG. 1 is a schottky barrier type HEMT. As the gate electrode 19, for example, a stacked structure of Au/Ni is used. A left side of the “/” is the material of the upper layer of a film stack, and the right side thereof indicates the material of the lower layer of a film stack. Furthermore, the semiconductor device 1 is not limited to the schottky barrier type HEMT, and may be a Metal Insulator Semiconductor (MIS) type HEMT in which a gate insulating film is interposed between the barrier layer 16 and the gate electrode 19.

The source electrode 17 and the barrier layer 16 form an ohmic contact with each other. Similarly, the drain electrode 18 and the barrier layer 16 form an ohmic contact with each other. That is, each of the source electrode 17 and the drain electrode 18 include a material which forms an ohmic contact with the barrier layer 16. As the source electrode 17 and the drain electrode 18, for example, a stacked structure of Al/Ti is used.

In a heterojunction structure of the channel layer 15 and the barrier layer 16, the lattice constant of the barrier layer 16 is smaller than the lattice constant of the channel layer 15, and thus distortion or stress occurs in the barrier layer 16. A piezoelectric polarization occurs in the barrier layer 16 according to a piezoelectric effect due to the distortion or stress, and two-dimensional electron gas (2DEG) is generated in the vicinity of a boundary surface between the channel layer 15 and the barrier layer 16. The two-dimensional electron gas forms the channel between the source electrode 17 and the drain electrode 18. The drain current passing through the channel is controlled by a schottky barrier generated by the junction between the gate electrode 19 and the barrier layer 16, i.e., the voltage state of the gate determines whether the channel is open or closed. In addition, the two-dimensional electron gas has high electron mobility, and thus the semiconductor device 1 can perform an extremely fast switching operation.

Here, the diode Di is configured from the buffer layer 13 which is formed of the p-type semiconductor layer 12 described above and an n-type semiconductor. The diode Di is inserted between the buffer layer 11 and the high resistance layer 14. When high voltage is applied to the drain electrode 18, and ground voltage VSS (0 V) is applied to the substrate 10, reverse bias is applied to the diode Di.

The carrier concentration of the p-type semiconductor layer 12 is set to be higher than the carrier concentration of the buffer layer 13. In addition, the concentration of the p-type dopants in the p-type semiconductor layer 12 is set to be higher than the concentration of the n-type dopants in the buffer layer 13. In general, a depletion layer extends in the diode to the semiconductor layer side at which the carrier concentration is lower than the other in the PN junction. In this embodiment, the carrier concentration of the p-type semiconductor layer 12 is higher than the carrier concentration of the buffer layer 13, and thus the depletion layer extends to the buffer layer 13 side. Accordingly, it is possible to prevent the depletion layer from reaching the buffer layer 11 on a lower side of the p-type semiconductor layer 12, and as a result thereof, it is possible to prevent leakage current from being increased.

The carrier concentration of the p-type semiconductor layer 12 is set to be greater than or equal to 1×10¹⁶ cm⁻³ and less than or equal to 5×10¹⁹ cm⁻³. Conditions of the carrier concentration are able to be replaced with conditions of the concentration of the dopants. That is, the concentration of the p-type dopants in the p-type semiconductor layer 12 is set to be greater than or equal to 1×10¹⁶ cm⁻³ and less than or equal to 5×10¹⁹ cm⁻³.

When the carrier concentration of the p-type semiconductor layer 12 is less than 1×10¹⁶ cm⁻³, the carrier concentration of the p-type semiconductor layer 12 may be lower than the carrier concentration of the buffer layer 13. For example, when undoped GaN is used as the buffer layer 13, the undoped carrier concentration of the p-type semiconductor layer 12 is approximately greater than or equal to 5×10¹⁵ cm⁻³ and less than or equal to 1×10¹⁶ cm⁻³. Accordingly, in order to have the carrier concentration of the p-type semiconductor layer 12 to be higher than the carrier concentration of the buffer layer 13, it is preferable that the carrier concentration of the p-type semiconductor layer 12 is greater than or equal to 1×10¹⁶ cm⁻³.

When the carrier concentration of the p-type semiconductor layer 12 is greater than 5×10¹⁹ cm⁻³, p-type dopant which are not activated are present in the p-type semiconductor layer 12, i.e., additional doping at a concentration above 5×10¹⁹ cm⁻³ does not result in the formation of additional carriers. Additionally, when the carrier concentration of the p-type semiconductor layer 12 is greater than 5×10¹⁹ cm⁻³, the uniformity of the crystallinity of the p-type semiconductor layer 12 is degraded. For these reasons, it is preferable that the carrier concentration of the p-type semiconductor layer 12 is less than or equal to 5×10¹⁹ cm⁻³.

2. Operation

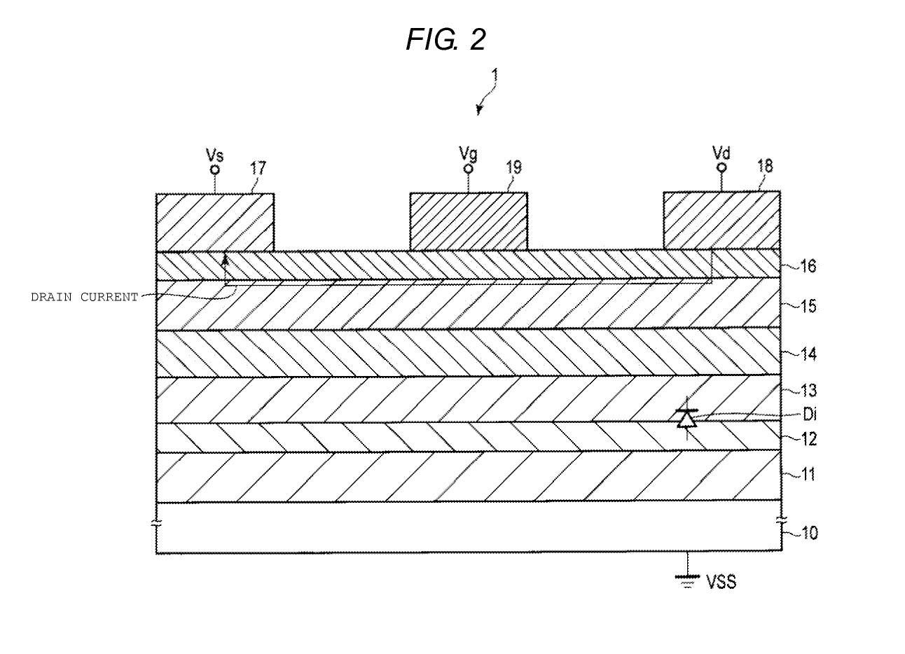

Next, an operation of the semiconductor device 1 configured as described above will be described. FIG. 2 is a schematic view illustrating the operation of the semiconductor device 1.

The semiconductor device 1, for example, is a normally-on-type semiconductor device. The semiconductor device 1, for example, is used as a switching element, and in the semiconductor device 1, a high voltage of approximately 200 V to 600 V may be applied to the drain electrode 18. A leakage current which occurs in the semiconductor device 1, specifically, a leakage current from the drain electrode 18 to the substrate 10, increases as the voltage applied to the semiconductor device 1 becomes higher. When the semiconductor device 1 is operated, a voltage of 0 V is applied to the substrate 10.

When the semiconductor device 1 is turned ON, for example, a gate voltage of Vg=0 V, a source voltage of Vs=0 V, and a drain voltage of Vd=200 V are applied. At this time, drain current flows between the drain electrode 18 and the source electrode 17 through the channel formed on the channel layer 15.

When the semiconductor device 1 is turned OFF, for example, the gate voltage of Vg=−15 V, the source voltage of Vs=0 V, and the drain voltage of Vd=200 V are applied. At this time, the thickness of the depletion layer which extends beneath the gate electrode 19 is extended, and the drain current is blocked from passing through the channel formed in the high resistance layer 15.

As described above, the buffer layer 13 which is formed of the p-type semiconductor layer 12 and the n-type semiconductor layer configures the diode Di. As among the p-type semiconductor layer 12 and the buffer layer 13 which configure the diode Di, the p-type semiconductor layer 12 forms the anode side, and the buffer layer 13 forms the cathode side of the diode Di.

In an OFF state of the semiconductor device 1, a high voltage is applied to the drain electrode 18, and a voltage of 0 V is applied to the substrate 10. At this time, a reverse bias is applied to the diode Di. Accordingly, the diode Di decreases a leakage current flowing between the drain electrode 18 and the substrate 10. Specifically, when a high voltage is applied to the drain electrode 18, the buffer layer 13 is depleted according to the width of an electric field from the drain electrode 18. When the semiconductor device 1 is in the OFF state, the channel is depleted, and there is no current leakage path in a horizontal direction (between the drain and the source), and thus leakage current in the horizontal direction is reduced. In addition, leakage current in a vertical direction (between the drain and the substrate) is reduced by the potential barrier of the PN junction configuring the diode Di.

Furthermore, in an ON state of the semiconductor device 1, leakage current from the drain electrode 18 to the substrate 10 is barely generated. However, when the drain voltage is further increased, leakage current from the drain electrode 18 to the substrate 10 may be generated, but even in such a circumstance, the potential barrier of the PN junction configuring the diode Di reduces the leakage current from the drain electrode 18 to the substrate 10.

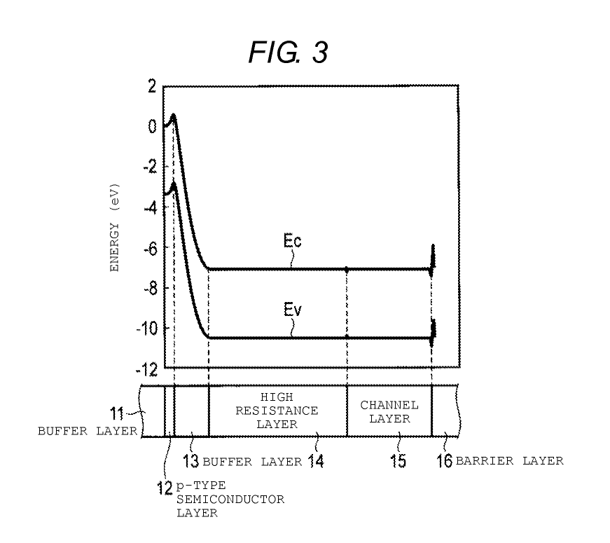

FIG. 3 is an energy band diagram of the semiconductor device 1. A horizontal axis of FIG. 3 corresponds to a thickness from the buffer layer 11 to the barrier layer 16, and a vertical axis indicates energy (eV). Ev of FIG. 3 indicates an energy level of an upper most in a valence band, and Ec indicates an energy level of a lower most in a conduction band. FIG. 3 is an experimental result when the drain voltage is Vd=9 V, and a voltage of 0 V is applied to the substrate.

As understood from FIG. 3, when a reverse bias is applied to the diode Di, an energy barrier (a potential barrier) increases in a boundary surface of the PN junction which is formed by the p-type semiconductor layer 12 and the buffer layer 13. That is, the thickness of the depletion layer in the diode Di increases as the reverse bias becomes higher, and thus leakage current in the vertical direction (of the device of FIG. 1) is reduced by the presence of the diode Di.

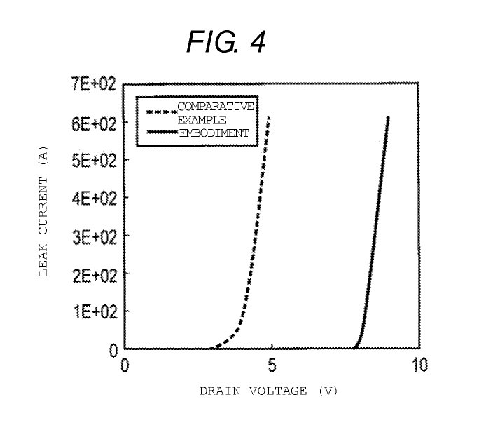

FIG. 4 is a graph illustrating a relationship between a drain voltage and a leak current. FIG. 4 is a result of measuring leakage current which flows from the drain electrode 18 to the substrate 10 when a drain voltage is applied between two terminals of the drain electrode 18 and the substrate 10. At this time, a voltage of 0 V is applied to the substrate 10. A horizontal axis of FIG. 4 indicates a drain voltage (V), and a vertical axis indicates a leak current (A). “E” in the horizontal axis of FIG. 4 indicates exponent notation having 10 as a base (low). In addition, a graph of this embodiment including the diode Di and a comparative example not including the diode Di (that is, a configuration excluding the p-type semiconductor layer 12 from FIG. 1) is illustrated in FIG. 4.

As understood from FIG. 4, the diode Di in which the reverse bias is applied in a state where the drain voltage is applied is inserted between the buffer layer 11 and the high resistance layer 14, and thus it is possible to reduce the leakage current flowing from the drain electrode 18 to the substrate 10. Furthermore, a threshold value (a breakdown voltage) of the reverse bias of the diode Di is able to be arbitrarily set according to the environment in which the semiconductor device 1 is used and the operation conditions.

3. Effect

As described above, in this embodiment, the p-type semiconductor layer 12 and the buffer layer 13 which is formed of n-type semiconductor layer are inserted (formed) between the buffer layer 11 and the high resistance layer 14 (or the channel layer 15) in the semiconductor device 1. The p-type semiconductor layer 12 and the buffer layer 13 configure the diode Di. Then, when a high voltage is applied to the drain electrode 18, a reverse bias is applied to the diode Di.

Therefore, according to this embodiment, when the semiconductor device 1 is operated, it is possible to reduce the leakage current flowing from the drain electrode 18 to the substrate 10. Accordingly, it is possible to produce a semiconductor device 1 having a small leakage current, and thus it is possible to reduce the consumed power of the semiconductor device 1.

In addition, the carrier concentration of the p-type semiconductor layer 12 is set to be higher than the carrier concentration of the buffer layer 13. Accordingly, the depletion layer of the diode Di is able to be controlled such that the depletion layer extends to the buffer layer 13 side of the diode Di, and thus it is possible to prevent the depletion layer from reaching the buffer layer 11 beneath the p-type semiconductor layer 12. Accordingly, even when an operating voltage of the semiconductor device 1 increases, it is possible to reduce the leakage current.

In addition, the high resistance layer 14 having resistance higher than resistance of the buffer layer 13 is disposed between the buffer layer 13 and the channel layer 15. The high resistance layer 14, for example, includes the nitride semiconductor doped with carbon (C). Accordingly, it is possible to achieve a higher breakdown voltage of the semiconductor device 1.

Herein, “stack” includes a case of overlapping by having another layer therebetween in addition to a case of overlapping in contact with each other. In addition, “provided on” includes a case of being provided by having another layer therebetween in addition to a case of being provided in directly contact with each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first semiconductor layer on a substrate;
a second semiconductor layer comprising a nitride semiconductor doped with p-type dopants on the first semiconductor layer;
a third semiconductor layer comprising an undoped nitride semiconductor on the second semiconductor layer;
a fourth semiconductor layer comprising an undoped nitride semiconductor on the third semiconductor layer; and
a fifth semiconductor layer on the fourth semiconductor layer, the fifth semiconductor layer comprising a nitride semiconductor having a band gap greater than a band gap of the fourth semiconductor layer.

2. The device according to claim 1, wherein a carrier concentration of the second semiconductor layer is higher than a carrier concentration of the third semiconductor layer.

3. The device according to claim 1, wherein a carrier concentration of the second semiconductor layer is greater than or equal to 1×10¹⁶ cm⁻³ and less than or equal to 5×10¹⁹ cm⁻³.

4. The device according to claim 1, wherein the second semiconductor layer is thinner than the third semiconductor layer.

5. The device according to claim 1, wherein the second semiconductor layer comprises Al_{X}In_{Y}Ga_{1-(X+Y)}N, where 0≦X<1, 0≦Y<1, and 0≦X+Y<1.

6. The device according to claim 1, wherein the third semiconductor layer comprises Al_{X}In_{Y}Ga_{1-(X+Y)}N, where 0≦X<1, 0≦Y<1, and 0≦X+Y<1.

7. The device according to claim 1, further comprising:
a sixth semiconductor layer between the third semiconductor layer and the fourth semiconductor layer, the sixth semiconductor layer having a higher resistance than a resistance of the third semiconductor layer.

8. The device according to claim 7, wherein the sixth semiconductor layer comprises a nitride semiconductor containing carbon.

9. A semiconductor device, comprising:
a first semiconductor layer on a substrate;
a second, p-type, semiconductor layer on the first semiconductor layer;
a third, n-type, semiconductor layer on the second semiconductor layer;
a fourth semiconductor layer comprising an undoped nitride semiconductor on the third semiconductor layer; and
a fifth semiconductor layer on the fourth semiconductor layer, the fifth semiconductor layer comprising a nitride semiconductor having a band gap greater than a band gap of the fourth semiconductor layer,
wherein the second and third semiconductor layers form a diode.

10. The semiconductor device of claim 9, further comprising:
first, second, and third electrodes on the fifth semiconductor layer, the second electrode interposed between the first and the third electrodes, and each of the first, second and third electrodes spaced from one another.

11. The semiconductor device of claim 10, wherein the second electrode is a gate electrode.

12. The semiconductor device of claim 11, wherein a negative voltage on the second electrode extends a depletion region inwardly of the fourth semiconductor layer.

13. The semiconductor device of claim 9, wherein the second and third semiconductor layers are nitride semiconductor layers.

14. The semiconductor device of claim 13, wherein the second semiconductor layer comprises Al_{X}In_{Y}Ga_{1-(X+Y)}N, where 0≦X<1, 0≦Y<1, and 0≦X+Y<1.

15. The semiconductor device of claim 13, wherein the first semiconductor layer comprises Al_{X}In_{Y}Ga_{1-(X+Y)}N, where 0≦X<1, 0≦Y<1, and 0≦X+Y<1.

16. A method of forming a semiconductor device, comprising:
providing a semiconductor substrate;
forming a first nitride semiconductor layer over the substrate
forming a diode over the substrate, the diode configured to provide a potential barrier in a direction of current flow through the diode toward the substrate;
forming a channel layer over the diode; and
forming a second nitride semiconductor layer over the channel layer, the second nitride semiconductor layer having a band gap greater than a band gap of the channel layer.

17. The method of claim 16, further comprising:
forming first, second, and third electrodes on the second nitride semiconductor layer, the second electrode interposed between the first and the third electrodes, and each of the first, second and third electrodes spaced from one another.

18. The method of claim 16, wherein the diode is formed by:
forming a first diode semiconductor layer of Al_{X}In_{Y}Ga_{1-(X+Y)}N and a p-type dopant, where 0≦X<1, 0≦Y<1, and 0≦X+Y<1; and
forming a second diode semiconductor layer of Al_{X}In_{Y}Ga_{1-(X+Y)}N over the first diode semiconductor layer, where 0≦X<1, 0≦Y<1, and 0≦X+Y<1.

19. The method of claim 17, wherein the second electrode is a gate electrode.

20. The method of claim 16, wherein the channel layer comprises an undoped nitride semiconductor.
